(19) United States
(12) Patent Application Publication
(10) Pub. No.: US 2002/0123240 A1
(43) Pub. Date: Sep. 5, 2002

(54) Electronic device manufacture

(75) Inventors: Michael K. Gallagher, Lansdale, PA (US); Yujian You, Lansdale, PA (US); Maureen Roche, Billerica, MA (US)

Correspondence Address: c/o EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 09/997,697

(22) Filed: Nov. 30, 2001

Related U.S. Application Data
(60) Provisional application No. 60/250,052, filed on Nov. 30, 2000.

(51) Int. Cl. H01L 21/31

(52) U.S. Cl. 438/781

(57) ABSTRACT

Disclosed are methods of manufacturing electronic devices, particularly integrated circuits, containing organic polysilica low dielectric constant materials. Such methods provide enhanced adhesion of polymeric materials to the organic polysilica dielectric materials.

### BACKGROUND OF THE INVENTION

The present invention relates generally to the field of manufacture of electronic devices. In particular, the present invention relates to the manufacture of integrated circuits containing low dielectric constant material.

As electronic devices become smaller, there is a continuing desire in the electronics industry to increase the circuit density in electronic components, e.g., integrated circuits, circuit boards, multichip modules, chip test devices, and the like without degrading electrical performance, e.g., crosstalk or capacitive coupling, and also to increase the speed of signal propagation in these components. One method of accomplishing these goals is to reduce the dielectric constant of the interlayer, or intermetal, insulating material used in the components.

A variety of organic and inorganic porous dielectric materials are known in the art in the manufacture of electronic devices, particularly integrated circuits. Suitable inorganic dielectric materials include silicon dioxide and organic polysilicas. Suitable organic dielectric materials include thermosets such as polyimides, polyarylene ethers, polyarylenes, polycyanurates, polybenzazoles, benzocyclobutenes and the like. Of the inorganic dielectrics, the alkyl silsesquioxanes such as methyl silsesquioxane are of increasing importance because of their lower dielectric constant.

A method for reducing the dielectric constant of interlayer, or intermetal, insulating material is to incorporate within the insulating film very small, uniformly dispersed pores or voids. In general, such porous dielectric materials are prepared by first incorporating a removable porogen into a B-staged dielectric material, disposing the B-staged dielectric material containing the removable porogen onto a substrate, curing the B-staged dielectric material and then removing the porogen to form a porous dielectric material. For example, U.S. Pat. No. 5,895,263 (Carter et al.) discloses a process for forming an integrated circuit containing porous organic polysilica dielectric material. U.S. Pat. No. 6,093,636 (Carter et al.) discloses a process for forming an integrated circuit containing porous thermoset dielectric material. In conventional processes, the dielectric material is typically cured under a non-oxidizing atmosphere, such as nitrogen, and optionally in the presence of an amine in the vapor phase to catalyze the curing process.

After the porous dielectric material is formed, it is subjected to conventional processing conditions of patterning, etching apertures, optionally applying a barrier layer and/or seed layer, metallizing or filling the apertures, planarizing the metallized layer, and then applying a cap layer or etch stop. These process steps may then be repeated to form another layer of the device.

A disadvantage of certain dielectric materials, including porous dielectric materials, is that other materials used in subsequent processing steps do not always sufficiently adhere to the surface of the dielectric material to allow for subsequent processing. For example, conventional polymeric materials such as photoresists and antireflective coatings do not readily adhere to the surface of dielectric materials containing methyl silsesquioxane, resulting in non-uniform layers of such polymeric materials. Such non-uniform layers may have areas totally devoid of photoresist or antireflective coating material and other areas where excessive polymeric material has built up. Uniform layers of photoresists and antireflective coatings are needed for subsequent patterning of the dielectric materials. Methyl silsesquioxane has not achieved widespread use in electronic devices because of this adherence problem.

There is thus a need for a process for manufacturing electronic devices containing alkyl and/or aryl silsesquioxane dielectric materials. There is further a need for improving the adherence of polymeric materials used in subsequent processing steps, such as conventional photoresists and antireflective coatings, to alkyl and/or aryl silsesquioxane dielectric materials.

U.S. Pat. No. 4,900,582 (Nakayama et al.) discloses a process for forming a silica-based film on a substrate including the steps of coating a solution for forming a silica-based film on a substrate, drying the coating and exposing the film to UV radiation in an atmosphere containing ozone. The silica compounds disclosed in this patent are halogenated silanes and alkoxysilanes. This patent does not disclose curing silica-based films in the absence of UV radiation. Further, this patent does not disclose a method of improving the adhesion of polymeric coatings to organic polysilica dielectric materials.

Japanese Patent Application 37353 (1977) discloses a method of densifying silica films by heat treatment of such films at about 750° C. in oxygen, nitrogen or air. Low temperature curing of the silica films is not disclosed.

### SUMMARY OF THE INVENTION

It has been surprisingly found that electronic devices containing dielectric material including organic polysilica dielectric material, such as alkyl and/or aryl silsesquioxane, can be prepared according to the present invention with the use of conventional polymeric materials such as photoresists and antireflective coatings. Uniform coatings of such polymeric materials have been achieved according to the present invention. It has further been surprisingly found that the present invention reduces or eliminates the need for cap layers, thus reducing the number of processing steps required to manufacture an electronic device.

In one aspect, the present invention provides a method for manufacturing an electronic device including the steps of: a) disposing on a substrate one or more B-staged organic polysilica dielectric matrix materials; and b) curing the one or more B-staged dielectric matrix materials in an oxidizing atmosphere, wherein the curing step is free of Uv radiation.

In a second aspect, the present invention provides a method of forming a cap layer on the surface of one or more B-staged organic polysilica dielectric matrix materials including the step of curing the one or more B-staged organic polysilica dielectric materials in an oxidizing atmosphere, wherein the curing step is free of UV radiation.

In a third aspect, the present invention provides a method for improving the adhesion of polymeric materials to organic polysilica dielectric materials including the step of curing one or more B-staged organic polysilica dielectric materials in an oxidizing atmosphere, wherein the curing step is free of UV radiation.

### BRIEF DESCRIPTION OF THE DRAWINGS

FIG. 1 illustrates a prior art electronic device after spin coating a conventional photoresist layer on a methyl silsesquioxane dielectric film, not to scale.

FIG. 2 illustrates a prior art electronic device after spin coating a conventional photoresist layer on a porous methyl silsesquioxane dielectric film, not to scale.

FIG. 3 illustrates an electronic device after spin coating a conventional photoresist layer on a methyl silsesquioxane dielectric film cured according to the present invention, not to scale.

FIG. 4 illustrates an electronic device after spin coating a conventional photoresist layer on a porous methyl silsesquioxane dielectric film cured according to the present invention, not to scale.

### DETAILED DESCRIPTION OF THE INVENTION

As used throughout this specification, the following abbreviations shall have the following meanings, unless the context clearly indicates otherwise: ° C.=degrees centigrade; UV=ultraviolet; nm=nanometer; g=gram; wt %=weight percent; L=liter; μm=micron=micrometer; and ppm=parts per million.

The term “alkyl” includes straight chain, branched and cyclic alkyl groups. The term “porogen” refers to a pore forming material, that is a polymeric material or particle dispersed in a dielectric material that is subsequently removed to yield pores, voids or free volume in the dielectric material. Thus, the terms “removable porogen,” “removable polymer” and “removable particle” are used interchangeably throughout this specification. The terms “pore,” “void” and “free volume” are used interchangeably throughout this specification. “Cross-linker” and “crosslinking agent” are used interchangeably throughout this specification. “Polymer” refers to polymers and oligomers, and also includes homopolymers and copolymers. The terms “oligomer” and “oligomeric” refer to dimers, trimers, tetramers and the like. “Monomer” refers to any ethylenically or acetylenically unsaturated compound capable of being polymerized or other compound capable of being polymerized by condensation. Such monomers may contain one or more double or triple bonds or groups capable of being polymerized by condensation.

The term “B-staged” refers to uncured organic polysilica dielectric matrix materials. By “uncured” is meant any dielectric material that can be polymerized or cured to form higher molecular weight materials, such as coatings or films. Such B-staged material may be monomeric, oligomeric or mixtures thereof. B-staged material is further intended to include mixtures of polymeric material with monomers, oligomers or a mixture of monomers and oligomers.

Unless otherwise noted, all amounts are percent by weight and all ratios are by weight. All numerical ranges are inclusive and combinable.

In conventional procedures for preparing electronic devices such as integrated circuits having organic polysilica dielectric material layers, B-staged organic polysilica dielectric material is first disposed on a substrate. The B-staged dielectric material is then cured typically in a non-oxidizing atmosphere, such as nitrogen, and optionally in the presence of a vapor phase amine catalyst to form a layer, coating or film of organic polysilica dielectric material on the substrate.

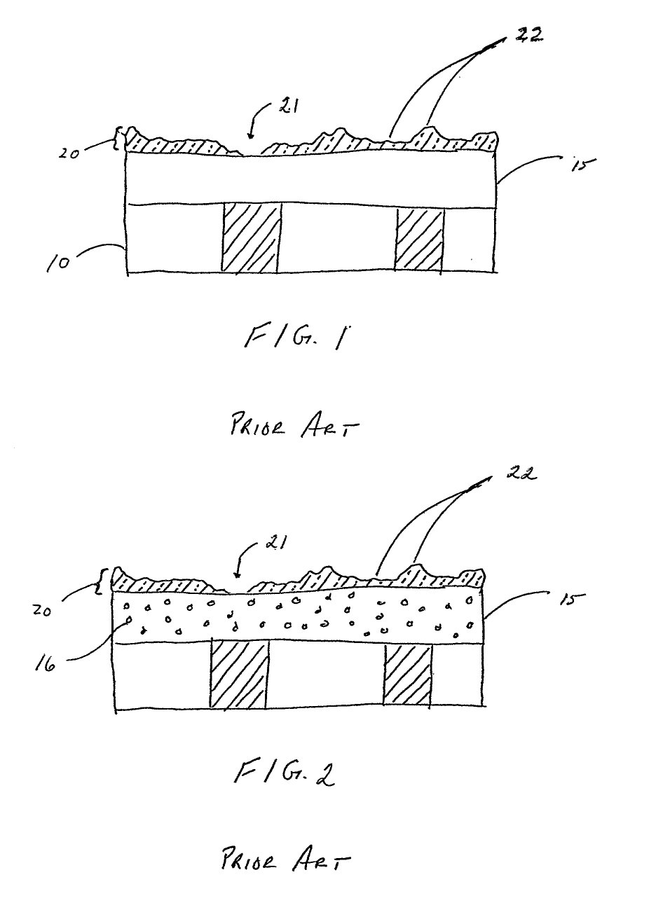

Once such organic polysilica dielectric material is cured, it is next patterned. Patterning is well known to those skilled in the art and requires disposing a photoresist layer on the surface of the organic polysilica dielectric material and optionally an antireflective coating between the photoresist layer and the dielectric material. Polymeric materials such as photoresists and antireflective coatings used in subsequent processing steps do not adhere sufficiently to certain conventionally prepared organic polysilica dielectric materials, particularly those containing methyl silsesquioxane. When conventional photoresists are disposed, such as by spin coating, on the surface of methyl silsesquioxane dielectric material the photoresist does not typically provide a uniform coating. FIG. 1 illustrates a conventional process for spin coating a conventional photoresist layer 20 on a methyl silsesquioxane dielectric film 15 disposed on a substrate 10 having metallic studs 12. The photoresist layer 20 typically has deficiencies or areas of little or missing photoresist 21 and areas of uneven thickness 22, exaggerated for clarity. FIG. 2 illustrates a conventional process for spin coating a conventional photoresist layer 20 on a methyl silsesquioxane dielectric film 15 containing pores 16 and having areas of little or missing photoresist 21 and areas of uneven thickness 22, exaggerated for clarity. Such deficiencies are problematic for the patterning of such methyl silsesquioxane dielectric material, whether porous or not.

These problems are reduced or avoided by the present invention. The present invention provides a method for manufacturing an electronic device including the steps of: a) disposing on a substrate one or more B-staged organic polysilica dielectric matrix materials; and b) curing the one or more B-staged dielectric matrix materials in an oxidizing atmosphere, wherein the curing step is free of UV radiation. Particularly suitable B-staged organic polysilica (or organic siloxane) dielectric materials useful in the present invention are any compounds including silicon, carbon, oxygen and hydrogen atoms and having the formula:

((RR¹SiO)ₐ(R²SiO_{1.5})_{b}(R³SiO_{1.5})_{c}(SiO₂)_{d})ₙ

wherein R, R¹, R² and R³ are independently selected from hydrogen, (C₁-C₆)alkyl, aryl, and substituted aryl; a, c and d are independently a number from 0 to 1; b is a number from 0.2 to 1; n is integer from about 3 to about 10,000; provided that a+b+c+d=1; and provided that at least one of R, R¹ and R² is not hydrogen. “Substituted aryl” refers to an aryl group having one or more of its hydrogens replaced by another substituent group, such as cyano, hydroxy, mercapto, halo, (C₁-C₆)alkyl, (C₁-C₆)alkoxy, and the like. In the above formula, a, b, c and d represent the mole ratios of each component. Such mole ratios of a, c and d can be varied between 0 and about 1. It is preferred that c is from 0 to about 0.8. It is further preferred that d is from 0 to about 0.8. In the above formula, n refers to the number of repeat units in the B-staged material. Preferably, n is an integer from about 3 to about 5,000. It will be appreciated that prior to any curing step, the B-staged organic polysilica dielectric matrix materials may include one or more of hydroxyl or alkoxy end capping or side chain functional groups. Such end capping or side chain functional groups are known to those skilled in the art.

Suitable organic polysilica dielectric matrix materials include, but are not limited to, silsesquioxanes, partially condensed halosilanes or alkoxysilanes such as partially condensed by controlled hydrolysis tetraethoxysilane having number average molecular weight of about 500 to about 20,000, organically modified silicates having the composition RSiO₃ or R₂SiO₂ wherein R is an organic substituent, and partially condensed orthosilicates having Si(OR)₄ as the monomer unit. Silsesquioxanes are polymeric silicate materials of the type RSiO_{1.5} where R is an organic substituent. Suitable silsesquioxanes are alkyl silsesquioxanes such as methyl silsesquioxane, ethyl silsesquioxane, propyl silsesquioxane, butyl silsesquioxane and the like; aryl silsesquioxanes such as phenyl silsesquioxane and tolyl silsesquioxane; and mixtures thereof. Suitable mixtures include alkyl/aryl silsesquioxane mixtures such as methyl silsesquioxane/phenyl silsesquioxane; mixtures of aryl silsesquioxanes such as phenyl silsesquioxane/tolyl silsesquioxane; and mixtures of alkyl silsesquioxanes such as methyl silsesquioxane/ethyl silsesquioxane. It is preferred that the organic polysilica material is includes a silsesquioxane, and more preferably that the silsesquioxane is methyl silsesquioxane. B-staged silsesquioxane materials include homopolymers of silsesquioxanes, copolymers of silsesquioxanes or mixtures thereof. Typically, the silsesquioxanes useful in the present invention are used as oligomeric materials, generally having from about 3 to about 10,000 repeating units.

It will be appreciated that a mixture of dielectric materials may be used, such as two or more organic polysilica dielectric materials or a mixture of one or more organic polysilicas with one or more other inorganic or organic dielectric materials. Particularly useful mixtures of dielectric materials include mixtures of alkyl silsesquioxanes such as methyl silsesquioxane/ethyl silsesquioxane, methyl silsesquioxane/tert-butyl silsesquioxane and methyl silsesquioxane/isobutyl silsesquioxane, mixtures of aryl silsesquioxane such as phenyl silsesquioxane/tolyl silsesquioxane, mixtures of alkyl/aryl silsesquioxanes such as methyl silsesquioxane/phenyl silsesquioxane, ethyl silsesquioxane/phenyl silsesquioxane, tert-butyl silsesquioxane/phenyl silsesquioxane, methyl silsesquioxane,/tolyl silsesquioxane, methyl silsesquioxane/tert-butyl silsesquioxane/phenyl silsesquioxane and mixtures of alkyl and/or aryl silsesquioxane with hydrido silsesquioxane such as methyl silsesquioxane/hydrido silsesquioxane, ethyl silsesquioxane/hydrido silsesquioxane, tert-butyl silsesquioxane/hydrido silsesquioxane, phenyl silsesquioxane/hydrido silsesquioxane and methyl silsesquioxane/phenyl silsesquioxane/hydrido silsesquioxane. Preferred mixtures of silsesquioxane are methyl silsesquioxane/hydrido silsesquioxane, methyl silsesquioxane/tert-butyl silsesquioxane, methyl silsesquioxane/phenyl silsesquioxane, phenyl silsesquioxane/hydrido silsesquioxane, methyl silsesquioxane/phenyl silsesquioxane/hydrido silsesquioxane and methyl silsesquioxane/tert-butyl silsesquioxane/hydrido silsesquioxane.

The B-staged organic polysilica dielectric materials are disposed on a substrate by any suitable means, such as, but not limited to, spin coating, spray coating or doctor blading. Such disposing means typically provide a film, layer or coating of B-staged dielectric material. The B-staged organic polysilica dielectric materials may be disposed on a substrate as is, but are typically combined with one or more organic solvents and/or optionally one or more porogens to form a B-staged dielectric composition. Any solvent that dissolves, disperses, suspends or otherwise is capable of delivering the B-staged organic polysilica dielectric materials to the substrate are suitable. Such organic solvents are well known in the art and include, but are not limited to, methyl isobutyl ketone, diisobutyl ketone, 2-heptanone, γ-butyrolactone, γ-caprolactone, ethyl lactate propyleneglycol monomethyl ether acetate, propyleneglycol monomethyl ether, diphenyl ether, anisole, n-amyl acetate, n-butyl acetate, cyclohexanone, N-methyl-2-pyrrolidone, N,N′-dimethylpropyleneurea, mesitylene, xylenes, or mixtures thereof. It is preferred that a composition including one or more B-staged organic polysilica dielectric materials and one or more organic solvents is disposed on a substrate. Once such a composition is disposed on the substrate, the solvent may be removed prior to or during the step of curing the B-staged organic polysilica dielectric material.

Substrates suitable for the present invention include, but are not limited to: silicon, silicon dioxide, silicon carbide, silicon germanium, silicon on insulator, glass, silicon nitride, ceramics, aluminum, copper, gallium arsenide, plastics, such as polycarbonate, circuit boards, such as FR-4 and polyimide, and hybrid circuit substrates, such as aluminum nitride-alumina. Such substrates may further include thin films deposited thereon, such films including, but not limited to: metal nitrides, metal carbides, metal silicides, metal oxides, and mixtures thereof. In a multilayer integrated circuit device, an underlying layer of insulated, planarized circuit lines can also function as a substrate.

After being deposited on a substrate, the B-staged dielectric material is then substantially cured to form a rigid, cross-linked dielectric material. Such cured dielectric material is typically a coating or film. The organic polysilica dielectric material may be cured by a variety of means such as by heating in an oven or on a hot plate, by plasma treatment or by corona discharge. When the organic polysilica material is thermally cured, it is typically heated at a temperature of up to about 450° C. A particularly useful temperature range for thermal curing is from 150° to 450° C., and preferably from 200° to 350° C. Thus, high temperature heat treatment, such as heating at about 550° to 750° C., during curing is avoided by the present invention. Alternatively, the organic polysilica dielectric material may be cured by treatment with a plasma. During such plasma treatment, the organic polysilica material may optionally be heated. Typically, the B-staged material is cured by heating at an elevated temperature, e.g. either directly or in a step-wise manner, e.g. 200° C. for 2 hours and then ramped up to 300° C. at a rate of 5° C. per minute and held at this temperature for 2 hours. Alternatively, the B-staged material may be cured by heating at a fixed temperature, such as from 225° to 275° C. for a period of time from 1 to 10 minutes, and preferably from 2 to 5 minutes. Such curing conditions are known to those skilled in the art and are dependent upon the particular B-staged organic polysilica dielectric material chosen.

According to the present invention, the B-staged organic polysilica material is cured in an oxidizing atmosphere. Any atmosphere is suitable provided it contains sufficient volatile oxidant to at least partially oxidize or otherwise rearrange the surface of the organic polysilica dielectric material. While not intending to be bound by theory, it is believed that curing the B-staged organic polysilica material in an oxidizing atmosphere oxidizes any organic groups on the surface of the material or alternatively causes an inversion of silicon atoms at the surface of the material such that any organic groups present are oriented into the matrix, i.e. away from the surface of the material. “Volatile oxidant” refers to any oxidant that has sufficient vapor pressure under the process conditions used to provide sufficient oxidant in the atmosphere to at least partially oxidize the organic polysilica dielectric material. Suitable amounts of oxidant in the atmosphere are typically about ≧10 ppm, preferably ≧25 ppm, more preferably about ≧50 ppm, and even more preferably about ≧100 ppm. Suitable oxidizing atmospheres include, but are not limited to, atmospheres including one or more of air, oxygen gas, ozone, oxides of nitrogen, oxides of carbon. oxides of sulfur and peroxides such as hydrogen peroxide, and preferably air or oxygen. Exemplary oxides of nitrogen include those having the formula NOₓ where x is a number from 0.5 to 2, such as N₂O and NO₂. Suitable oxides of carbon include carbon monoxide and carbon dioxide. It will be appreciated by those skilled in the art that suitable oxidizing atmospheres include atmospheres containing mixtures of inert gas with a volatile oxidant. Inert gases include, but are not limited to, nitrogen, argon and helium. Suitable inert gas/oxidant atmospheres include, but are not limited to, nitrogen/oxygen, nitrogen/air, argon/oxygen, argon/air, helium/oxygen and helium/air. In one embodiment, the B-staged organic dielectric material is cured in an oxygen plasma. The curing step of the present invention is free of UV radiation.

Typically, the B-staged organic polysilica dielectric materials are treated or cured in an oxidizing atmosphere for a time sufficient to at least partially oxidize the organic polysilica material. Such time depends upon the particular organic polysilica dielectric material selected as well as the curing conditions employed. In general, such treatment or curing time is that time sufficient to provide a cured organic polysilica dielectric material having a lower contact angle as compared to the same organic polysilica material cured in a non-oxidizing atmosphere, as measured on a contact angle goniometer.

In another embodiment, the organic polysilica dielectric materials may be porous. Such porous dielectric materials have reduced dielectric constants as compared with the same dielectric material in the absence of pores. Porous organic polysilica dielectric materials are typically prepared by first incorporating a removable porogen into a B-staged organic polysilica dielectric material, disposing the B-staged organic polysilica dielectric material containing the removable porogen onto a substrate, curing the B-staged dielectric material and then removing the polymer to form a porous organic polysilica dielectric material. Thus, it is preferred that the B-staged organic polysilica dielectric matrix materials of the present invention further include one or more porogens.

The porogens useful in the present invention are any which may be removed providing voids, pores or free volume in the organic polysilica dielectric material chosen and reduce the dielectric constant (“k”) of such material. A low-k dielectric material is any material having a dielectric constant less than about 4.

A wide variety of removable porogens may be used in the present invention. The removable porogens may be porogen polymers or particles or may be co-polymerized with an organic polysilica dielectric monomer to form a block copolymer having a labile (removable) component. Preferably, the removable porogen is substantially non-aggregated or non-agglomerated in the B-staged dielectric material. Such non-aggregation or non-agglomeration reduces or avoids the problem of killer pore or channel formation in the dielectric matrix. It is preferred that the removable porogen is a porogen particle. It is further preferred that the porogen particle is substantially compatible with the B-staged dielectric matrix material. By “substantially compatible” is meant that a composition of B-staged dielectric material and porogen is slightly cloudy or slightly opaque. Preferably, “substantially compatible” means at least one of a solution of B-staged dielectric material and porogen, a film or layer including a composition of B-staged dielectric material and porogen, a composition including a dielectric matrix material having porogen dispersed therein, and the resulting porous dielectric material after removal of the porogen is slightly cloudy or slightly opaque. To be compatible, the porogen must be soluble or miscible in the B-staged dielectric material, in the solvent used to dissolve the B-staged dielectric material or both. Suitable compatibilized porogens are those disclosed in co-pending U.S. patent application Ser. No. 09/460,326 (Allen et al.). Preferably, the compatibilized porogen includes as polymerized units at least one compound selected from silyl containing monomers or poly(alkylene oxide) monomers. Other suitable removable particles are those disclosed in U.S. Pat. No. 5,700,844.

Substantially compatibilized porogens, typically have a molecular weight in the range of 5,000 to 1,000,000, preferably 10,000 to 500,000, and more preferably 10,000 to 100,000. The polydispersity of these materials is in the range of 1 to 20, preferably 1.001 to 15, and more preferably 1.001 to 10. It is preferred that such substantially compatibilized porogens are cross linked. Typically, the amount of cross-linking agent is at least about 1% by weight, based on the weight of the porogen. Up to and including 100% cross-linking agent, based on the weight of the porogen, may be effectively used in the particles of the present invention. It is preferred that the amount of cross-linker is from about 1% to about 80%, and more preferably from about 1% to about 60% Suitable block copolymers having labile components are those disclosed in U.S. Pat. Nos. 5,776,990 and 6,093,636. Such block copolymers may be prepared, for example, by using as pore forming material highly branched aliphatic esters that have functional groups that are further functionalized with appropriate reactive groups such that the functionalized aliphatic esters are incorporated into, i.e. copolymerized with, the vitrifying polymer matrix.

The removable porogens are typically added to the B-staged organic polysilica dielectric materials of the present invention in an amount sufficient to provide the desired lowering of the dielectric constant. For example, the porogens may be added to the B-staged dielectric materials in any amount of from about 1 to about 90 wt %, based on the weight of the B-staged dielectric material, preferably from 10 to 80 wt %, more preferably from 15 to 60 wt %, and even more preferably from 20 to 30 wt %.

When the removable porogens are not components of a block copolymer, they may be combined with the B-staged organic polysilica dielectric material by any methods known in the art. Typically, the B-staged material is first dissolved in a suitable high boiling solvent, such as methyl isobutyl ketone, diisobutyl ketone, 2-heptanone, γ-butyrolactone, γ-caprolactone, ethyl lactate propyleneglycol monomethyl ether acetate, propyleneglycol monomethyl ether, diphenyl ether, anisole, n-amyl acetate, n-butyl acetate, cyclohexanone, N-methyl-2-pyrrolidone, N,N′-dimethylpropyleneurea, mesitylene, xylenes, or mixtures thereof to form a solution. The porogens are then dispersed or dissolved within the solution. The resulting composition (e.g. dispersion, suspension or solution) is then deposited on a substrate by methods known in the art for depositing B-staged dielectric materials.

To be useful as porogens in forming porous organic polysilica dielectric materials, the porogens of the present invention must be at least partially removable under conditions which do not adversely affect the dielectric material, preferably substantially removable, and more preferably completely removable. By “removable” is meant that the polymer depolymerizes or otherwise breaks down into volatile components or fragments which are then removed from, or migrate out of, the dielectric material yielding pores or voids. Such resulting pores or voids may fill with any carrier gas used in the removal process. Any procedures or conditions which at least partially remove the porogen without substantially degrading the dielectric material, that is, where less than 5% by weight of the dielectric material is lost, may be used. It is preferred that the porogen is substantially removed. Typical methods of removal include, but are not limited to: exposure to heat, pressure or radiation such as, but not limited to, actinic, IR, microwave, UV, x-ray, gamma ray, alpha particles, neutron beam or electron beam. It will be appreciated that more than one method of removing the porogen or polymer may be used, such as a combination of heat and actinic radiation. It is preferred that the dielectric material is exposed to heat or UV light to remove the porogen. It will also be appreciated by those skilled in the art that other methods of porogen removal, such as by atom abstraction, may be employed.

The porogens of the present invention can be thermally removed under vacuum, nitrogen, argon, mixtures of nitrogen and hydrogen, such as forming gas, or other inert or reducing atmosphere, as well as under oxidizing atmospheres. Preferably, the porogens are removed under inert or reducing atmospheres. The porogens of the present invention may be removed at any temperature that is higher than the thermal curing temperature and lower than the thermal decomposition temperature of the dielectric matrix material. Typically, the porogens of the present invention may be removed at temperatures in the range of 150° to 450° C. and preferably in the range of 250° C. to 425° C. Under preferable thermal porogen removal conditions, the organic polysilica dielectric material is heated to about 350° to 400° C. It will be recognized by those skilled in the art that the particular removal temperature of a thermally labile porogen will vary according to composition of the porogen. Such heating may be provided by means of an oven or microwave. Typically, the porogens of the present invention are removed upon heating for a period of time in the range of 1 to 120 minutes. After removal from the dielectric matrix material, 0 to 20% by weight of the porogen typically remains in the porous dielectric material.

In another embodiment, when a porogen of the present invention is removed by exposure to radiation, the porogen polymer is typically exposed under an inert atmosphere, such as nitrogen, to a radiation source, such as, but not limited to, visible or ultraviolet light. While not intending to be bound by theory, it is believed that porogen fragments form, such as by radical decomposition, and are removed from the matrix material under a flow of inert gas. The energy flux of the radiation must be sufficiently high such that porogen particles are at least partially removed.

Upon removal of the porogens, a porous dielectric material having voids is obtained, where the size of the voids is preferably substantially the same as the particle size of the porogen. The resulting dielectric material having voids thus has a lower dielectric constant than such material without such voids. In general, pore sizes of up to about 1,000 nm, such as that having a mean particle size in the range of about 0.5 to about 1000 nm, are obtained. It is preferred that the mean pore size is in the range of about 0.5 to about 200 nm, more preferably from about 0.5 to about 50 nm, and most preferably from about 1 nm to about 20 nm.

The porogen may be removed any time after curing of the B-staged organic polysilica dielectric material. For example, the porogens may suitably be removed during or after curing of the B-staged organic polysilica dielectric material, after exposure, after etching, after barrier or seed layer deposition, after aperture fill or metallization, or after planarization. For example, any porogens may be at least partially removed from the organic polysilica dielectric material during the curing of the B-staged material in an oxygen containing atmosphere such as, but not limited to, an oxygen plasma. Thus the curing conditions may be adjusted such that any porogen present in the B-staged organic polysilica dielectric material may optionally be at least partially removed. For example, increasing the temperature during the cure step or the curing time tends to increase the amount of porogens removed. It will be appreciated by those skilled in the art that the curing conditions may be selected such that substantially none of the porogen is removed or such that substantially all of the porogen is removed during the curing step. Thus, the present invention provides for a two-step process of removing the porogens after curing of the B-staged organic polysilica material and one-step process for curing a B-staged organic polysilica dielectric material and at least partially removing porogens to form a porous organic polysilica dielectric material. It is preferred that any porogens are removed after barrier or seed layer deposition, and more preferably after planarization. Thus, a two-step removal process is preferred.

After curing the B-staged organic polysilica dielectric material, a film, layer or coating of organic polysilica dielectric material is obtained. Once cured, the organic polysilica dielectric material is typically patterned. Such patterning typically involves (i) coating the dielectric material layer with a positive or negative photoresist, such as those marketed by Shipley Company (Marlborough, Mass.); (ii) imagewise exposing, through a mask, the photoresist to radiation, such as light of appropriate wavelength or e-beam; (iii) developing the image in the resist, e.g., with a suitable developer; and (iv) transferring the image through the dielectric layer to the substrate with a suitable transfer technique such as reactive ion etching. Such etching creates apertures in the dielectric material. Optionally, an antireflective coating is disposed between the photoresist layer and the dielectric matrix material. In the alternative, an antireflective coating may be applied to the surface of the photoresist. Such lithographic patterning techniques are well known to those skilled in the art.

In still another embodiment, the present invention provides a method of forming a cap layer on the surface of one or more B-staged organic polysilica dielectric matrix materials including the step of curing the one or more B-staged organic polysilica dielectric materials in an oxidizing atmosphere, wherein the curing step is free of UV radiation. Upon formation of a film of an organic polysilica dielectric material, treatment or curing of the material in an oxidizing atmosphere without exposure to UV radiation for a period of time provides a skin or layer on the surface of the dielectric material. Such skin or layer has a higher silicon-oxygen content in the surface as compared to the same dielectric material treated or cured in a non-oxidizing atmosphere. While not intending to be bound by theory, it is believed that such skin or layer includes silicon dioxide. Such skin may be formed by oxidation of any organic groups present at the surface or by inversion of silicon atoms at the surface such that any organic groups are directed into the bulk matrix material, i.e. away from the surface. This skin or layer functions as a cap layer for the organic polysilica dielectric material. Such cap layer improves the elastic modulus of the dielectric material for chemical mechanical planarization and improves thermal conductivity for heat management.

While not intending to be bound by theory, it is believed that the curing of the B-staged organic polysilica dielectric material in an oxidizing atmosphere affects the surface of the dielectric material. Such surface effects can be observed by changes in contact angle. Thus, organic polysilica material cured in an oxidizing atmosphere is substantially more compatible with subsequently applied polymeric materials than such dielectric material cured in non-oxidizing atmospheres. Organic polymeric materials, such as photoresists and/or antireflective coatings applied to the surface of such organic polysilica dielectric materials cured in an oxidizing atmosphere form substantially uniform layers across the surface of the substrate.

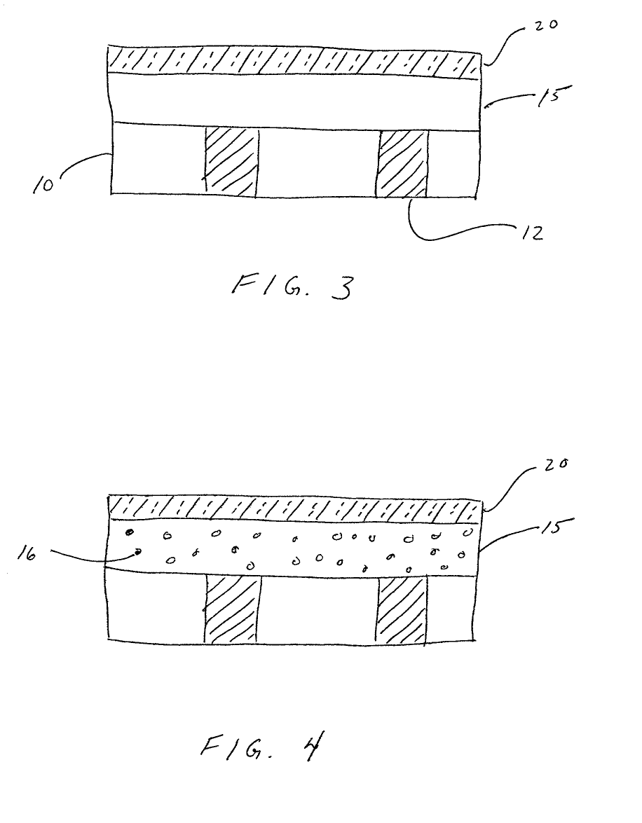

Thus, the present invention provides a method for improving the adhesion of polymeric materials to organic polysilica dielectric materials including the step of curing one or more B-staged organic polysilica dielectric materials in an oxidizing atmosphere. An advantage of the present invention is that conventional polymeric materials used in patterning processes, i.e. conventional photoresists and antireflective coatings, have sufficient adherence to the cured organic polysilica dielectric to allow patterning of the dielectric material. For example, FIG. 3 illustrates a uniform photoresist layer 20 on the surface of an organic polysilica dielectric material 15 disposed on a substrate 10 containing vertical metal studs 12, not to scale. Likewise, FIG. 4 illustrates a uniform photoresist layer 20 on the surface of an organic polysilica dielectric material 15 containing pores 16, not to scale. Such pores 16 are not shown to scale and are shown as substantially spherical. It will be appreciated that the pores in such porous dielectric material may be any suitable shape, preferably substantially spherical and more preferably spherical.

After the apertures are formed in the dielectric material, barrier and/or seed layers may optionally be deposited. Such barrier layers are typically formed from conductive or non-conductive materials, such as tantalum and tantalum alloys, and are deposited by chemical vapor deposition or physical vapor deposition techniques. Seed layers, when used, may be applied to the dielectric material as the first metal layer or applied to a previously deposited barrier layer. Suitable seed layers include copper or copper alloys. When a seed layer is used without a barrier layer, it is preferred that the seed layer is not copper. Such seed layers may also be deposited by chemical vapor deposition (“CVD”) or physical vapor deposition (“PVD”) and are thin as compared to metallization layers. Alternatively, seed layers may be applied electrolessly. Such seed layers include catalysts for subsequent electroless plating, such as electroless metallization or filling of the apertures.

Following such barrier and/or seed layer deposition, the aperture may be metallized or filled, such as with copper or copper alloy. Such metallization may be by any means, but is preferably at least partially electrolytic, and more preferably electrolytic. Methods of metallizing such apertures are well known to those skilled in the art. For example, ULTRAFILLTM 2001 EP copper deposition chemistries, available from Shipley Company (Marlborough, Mass.), may be used for electrolytic copper metallization of apertures.

In the alternative, the apertures may be metallized or filled electrolessly without the need for barrier or seed layers. If apertures are electrolessly metallized with copper, a barrier layer is preferred.

The deposited metal layer is typically planarized, such as by chemical mechanical polishing (“CMP”). Such CMP techniques are well known to those skilled in the art.

The following examples are presented to illustrate further various aspects of the present invention, but are not intended to limit the scope of the invention in any aspect.

### EXAMPLE 1

Silicon wafers (6 inch or 15 cm) were coated with a 30% solids composition of methyl silsesquioxane and a substantially compatible removable porogen using a GCA track. The composition was spin coated on the wafers at 200 rpm and then a film was spread at 3000 rpm. Excess material was removed from the back side of the wafer using a conventional edge bead remover and back side rinse agent. The films were then processed on a hot plate at 90° C. to partially remove the solvent. The wafers were then processed under a nitrogen atmosphere at an elevated furnace temperatures and at various hold times according to Table 1. After this processing, contact angle measurements were made on the films using a water droplet. The contact angle is indicative of the surface energy and can indicate whether a second coating such as a photoresist can be applied successfully on the surface and generate a uniform film.

Photoresist, UVTM 210 photoresist, available from Shipley Company (Marlborough, Mass.), was applied to the methyl silsesquioxane films on the wafers using standard application conditions. Some wafers were primed with hexamethyldisilane (“HMDS”) prior to application of the photoresist. The coating quality of the photoresist was evaluated by visual inspection following application of the photoresist to the methyl silsesquioxane film. The results are reported in Table 1.

TABLE 1

| | Furnace | | | | |
|---|---|---|---|---|---|
| | Temperature | Hold Time | Contact Angle | HMDS | Photoresist |
| Sample | (° C.) | (minutes) | (degrees) | Prime | Coating Quality |
| Control A | 425 | 60 | 103 | yes | poor, outer edge only |
| Control B | — | — | 77 | no | — |
| C1* | 250 | 5 | 86 | yes | good uniform film |
| | | | | no | incomplete coverage |
| C2* | 250 | 120 | 93 | yes | poor, outer edge only |
| | | | | no | poor, outer edge only |
| C3* | 300 | 5 | 95 | yes | poor, outer edge only |
| | | | | no | poor, outer edge only |
| C4* | 300 | 120 | 96 | yes | poor, outer edge only |
| | | | | no | poor, outer edge only |
| C5* | 275 | 60 | 93 | yes | poor, outer edge only |
| | | | | no | poor, outer edge only |

*Comparative

From the above data, it can be seen that short cure times and low temperatures yielded better films, although in almost every case the photoresist coating quality was poor. Primed wafers produced a better coating.

Comparative sample C1 having the good uniform photoresist coating was imaged at 248 nm. After exposure, this sample had a resolution of only 1 μm because the photoresist peeled off during development using a commercially available developer. Thus, although a good uniform coating of photoresist was obtained with comparative sample C1, the adhesion of the photoresist to the substrate was poor.

### EXAMPLE 2

The procedure of Example 1 was repeated except that the methyl silsesquioxane film was cured in air instead of under nitrogen and the photoresist was Shipley ULTRA™ I-123 photoresist, available from Shipley Company (Marlborough, Mass.). The cure time was varied from 1 minute to 5 minutes. The results are reported in Table 2.

TABLE 2

| | Furnace | | | | |
|---|---|---|---|---|---|
| | Temperature | Hold Time | Contact Angle | HMDS | Photoresist |
| Sample | (° C.) | (minutes) | (degrees) | Prime | Coating Quality |
| 1 | 250 | 1 | 74 | no | uniform and complete coating |
| | | | | | but contained defects and gels |
| 2 | 250 | 5 | 68 | no | uniform and complete coating |
| | | | | | with no visible defects |

From the above data, it can clearly be seen that by curing an organic polysilica dielectric material, particularly methyl silsesquioxane, in an oxidizing atmosphere, the coating quality of subsequently applied polymeric materials is greatly improved. Also, the processing temperature of such organic polysilica materials is greatly reduced as compared to curing under nitrogen.

The refractive index of Sample 2 was also measured using a THERMAWAVE™ optiprobe instrument. The refractive index was found to be 1.42 as compared to 1.36 for a control sample of cured ethyl silsesquioxane where the porogen has been removed. The higher refractive index of Sample 2 clearly demonstrates that the porogens in the methyl silsesquioxane survived the curing process and thus remained in the dielectric material.

### EXAMPLE 3

Silicon wafers (6 inch or 15 cm) were coated with a 30% solids composition of methyl silsesquioxane that did not contain any removable porogen to form a methyl silsesquioxane film.

The methyl silsesquioxane was applied under the same process conditions as those described in Example 1. The methyl silsesquioxane was cured under a nitrogen flow open to the air at 250° C. for up to 300 seconds and the contact angle for each sample was determined. These results are reported in Table 3.

TABLE 3

| | Cure Time | Contact Angle |
|---|---|---|
| Sample | (seconds) | (degrees) |
| Control 3 | 0 | 77 |
| 3 | 75 | 68 |
| 4 | 300 | 77 |

These data clearly demonstrate that curing an organic polysilica dielectric material such as methyl silsesquioxane in an oxidizing atmosphere provides a reduced contact angle as compared to a control sample of methyl silsesquioxane cured in a nitrogen atmosphere (contact angle=103°).

An antireflective coating, AR3™ antireflective coating available from Shipley Company (Marlborough, Mass.), was applied to samples 3 and 4. The coated samples were then visually inspected to determine the quality of the antireflective coating. In both samples 3 and 4, uniform, good quality antireflective coatings were obtained on the organic polysilica dielectric material.

### EXAMPLE 4

A silicon wafer was coated with a 30% solids composition of methyl silsesquioxane and a substantially compatible removable porogen according to the procedure of Example 1. This sample, Sample 5, was cured under the conditions of Sample 2 in Example 2. UVTM 210 photoresist was applied to cured Sample 5 using standard application conditions. The sample was exposed at 248 nm using conventional techniques and developed using a commercially available developer, resulting in resolution of 180 nm trenches. No peeling or lift-off of the photoresist was observed during development. Thus, the adhesion of the photoresist to the organic polysilica dielectric material was very good.

What is claimed is:

1. A method for manufacturing an electronic device comprising the steps of:
a) disposing on a substrate one or more B-staged organic polysilica dielectric matrix materials; and
b) curing the one or more B-staged dielectric matrix materials in an oxidizing atmosphere;
wherein the curing step is free of UV radiation.

2. The method of claim 1 wherein the one or more B-staged organic polysilica dielectric matrix materials have the formula:
((RR¹SiO)ₐ(R²SiO_{1.5})_{b}(R³SiO_{1.5})_{c}(SiO₂)_{d})ₙ
wherein R, R¹, R² and R³ are independently selected from hydrogen, (C₁-C₆)alkyl, aryl, and substituted aryl; a, c and d are independently a number from 0 to 1; b is a number from 0.2 to 1; n is integer from about 3 to about 10,000; provided that a+b+c+d=1; and provided that at least one of R, R¹ and R² is not hydrogen.

3. The method of claim 1 wherein the one or more B-staged organic polysilica dielectric matrix materials are selected from silsesquioxanes, partially condensed halosilanes or alkoxysilanes, organically modified silicates having the composition RSiO₃ or R₂SiO₂ wherein R is an organic substituent, and partially condensed orthosilicates having Si(OR)₄ as the monomer unit.

4. The method of claim 1 wherein the one or more B-staged organic polysilica dielectric matrix materials are selected from alkyl silsesquioxanes, aryl silsesquioxanes and mixtures thereof.

5. The method of claim 4 wherein the one or more B-staged organic polysilica dielectric matrix materials are selected from methyl silsesquioxane, ethyl silsesquioxane, propyl silsesquioxane, butyl silsesquioxane, phenyl silsesquioxane, tolyl silsesquioxane, mixtures of methyl silsesquioxane and phenyl. silsesquioxane, and mixtures thereof.

6. The method of claim 1 wherein the B-staged organic polysilica dielectric matrix material comprises one or more porogens.

7. The method of claim 1 wherein the oxidizing atmosphere comprises one or more of air, oxygen gas, ozone, oxides of nitrogen, oxides of carbon, oxides of sulfur or peroxides.

8. The method of claim 7 wherein the oxidizing atmosphere comprises air or oxygen gas.

9. The method of claim 1 wherein the oxidizing atmosphere contains an oxidant in an amount of about 10 ppm or greater.

10. The method of claim 1 wherein the oxidizing atmosphere contains an oxidant in an amount of 25 ppm or greater.

11. The method of claim 1 wherein the one or more B-staged organic polysilica dielectric matrix materials are cured by plasma treatment or corona discharge.

12. The method of claim 1 wherein the curing step further comprises heating the one or more B-staged organic polysilica materials at a temperature of up to about 450° C.

13. A method of forming a cap layer on the surface of one or more B-staged organic polysilica dielectric matrix materials comprising the step of curing the one or more B-staged organic polysilica dielectric materials in an oxidizing atmosphere; wherein the curing step is free of UV radiation.

14. The method of claim 13 wherein the one or more B-staged organic polysilica dielectric matrix materials are selected from silsesquioxanes, partially condensed halosilanes or alkoxysilanes, organically modified silicates having the composition RSiO₃ or R₂SiO₂ wherein R is an organic substituent, and partially condensed orthosilicates having Si(OR)₄ as the monomer unit.

15. The method of claim 13 wherein the one or more B-staged organic polysilica dielectric matrix materials are selected from alkyl silsesquioxanes, aryl silsesquioxanes and mixtures thereof.

16. The method of claim 13 wherein the oxidizing atmosphere contains an oxidant in an amount of about 10 ppm or greater.

17. The method of claim 13 wherein the curing step further comprises heating the one or more B-staged organic polysilica materials at a temperature of up to about 450° C.

18. A method for improving the adhesion of polymeric materials to organic polysilica dielectric materials comprising the step of curing B-staged organic polysilica dielectric materials in an oxidizing atmosphere; wherein the curing step is free of UV radiation.

19. The method of claim 18 wherein the one or more B-staged organic polysilicadielectric matrix materials are selected from silsesquioxanes, partially condensed halosilanes or alkoxysilanes, organically modified silicates having the composition RSiO₃ or R₂SiO₂ wherein R is an organic substituent, and partially condensed orthosilicates having Si(OR)₄ as the monomer unit.

20. The method of claim 18 wherein the one or more B-staged organic polysilica dielectric matrix materials are selected from alkyl silsesquioxanes, aryl silsesquioxanes and mixtures thereof.
